(19) United States
(12) Patent Application Publication
(10) Pub. No.: US 2023/0236223 A1
(43) Pub. Date: Jul. 27, 2023

(54) INSPECTION DEVICE

(71) Applicant: YOKOWO CO., LTD., Kita-ku, Tokyo (JP)

(72) Inventor: Tomohisa HOSHINO, Tomioka-Shi, Gunma (JP)

(73) Assignee: YOKOWO CO., LTD., Kita-ku, Tokyo (JP)

(21) Appl. No.: 18/010,464

(22) PCT Filed: Jun. 11, 2021
(86) PCT No.: PCT/JP2021/022250

§ 371 Date: Dec. 15, 2022

(30) Foreign Application Priority Data
Jun. 22, 2020 (JP) 2020-106767

(51) Int. Cl. G01R 1/073

(52) U.S. Cl. CPC G01R 1/07314

(57) ABSTRACT

An inspection device comprising: a plurality of plungers; and a connection part electrically connecting at least some of the plungers of the plurality of plungers to each other.

### TECHNICAL FIELD

The present invention relates to an inspection device.

### BACKGROUND ART

Various inspection devices have been developed for inspecting characteristics of electronic devices such as integrated circuits (ICs). As disclosed in Patent Document 1, an inspection device includes a plurality of plungers. In Patent Document 1, each plunger includes a tip contactor and a columnar part connected to the tip contactor.

### RELATED DOCUMENT

### Patent Document

Patent Document 1: Japanese Unexamined Patent Publication No. 2014-25737

### SUMMARY OF THE INVENTION

### Technical Problem

As disclosed in Patent Document 1, the inspection device may include the plurality of plungers. In this case, the individual plungers may be supplied with a potential through separate electrical paths to commonalize potential of the plurality of plungers. However, the use of such electrical paths may complicate a structure of the inspection device.

An example of an object of the present invention is to commonalize potential of the plurality of plungers with a simple structure. Other object of the present invention will be apparent from the description of the present specification.

### Solution to Problem

One aspect of the present invention is an inspection device including a plurality of plungers, and a connection part electrically connecting at least some of the plungers of the plurality of plungers to each other.

### Advantageous Effects of Invention

According to the above aspect of the present invention, the potential of the plurality of plungers can be commonalized with a simple structure.

### BRIEF DESCRIPTION OF THE DRAWINGS

FIG. 1 is a plan view of an inspection device according to an embodiment.

FIG. 2 is a cross-sectional view taken along line A-A′ of FIG. 1.

FIG. 3 is a perspective cross-sectional view showing the details of the inspection device according to the embodiment.

FIG. 4 is a cross-sectional view for describing the details of a first plunger and a first pin plate.

FIG. 5 is a cross-sectional view for describing a method of manufacturing the first plunger according to the embodiment.

### DESCRIPTION OF EMBODIMENTS

In the following, an embodiment of the present invention will be described with reference to the drawings. It should be noted that, in all drawings, similar components are designated by the same reference numerals, and the description thereof will not be repeated.

In the present specification, ordinal numbers, such as “first”, “second”, and “third”, are merely used to distinguish similarly named configurations unless otherwise noted, and do not imply any particular feature of the configuration, such as order or importance.

### Embodiment 1

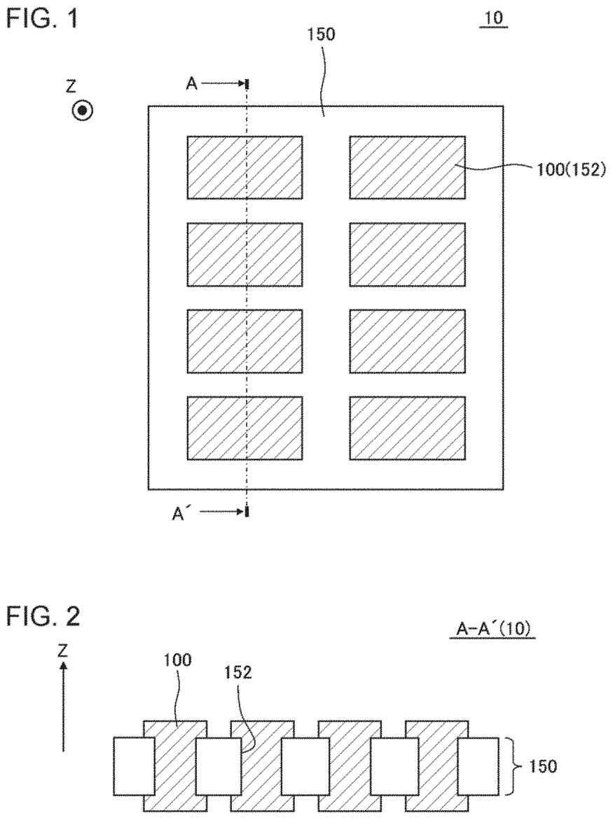

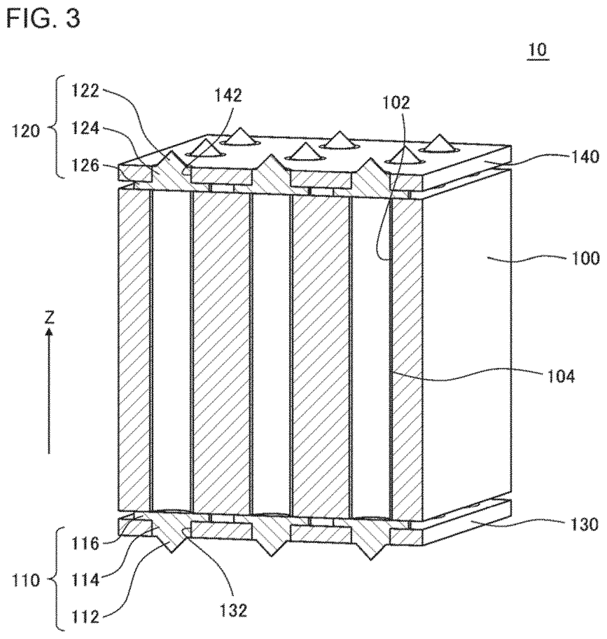

FIG. 1 is a plan view of an inspection device 10 according to Embodiment 1. FIG. 2 is a cross-sectional view taken along line A-A′ of FIG. 1. FIG. 3 is a perspective cross-sectional view showing the details of the inspection device 10 according to Embodiment 1.

In FIG. 1, a white circle with a black dot indicating a vertical direction Z means that a direction from the back to the front of the paper surface is an upward direction of the vertical direction Z, and a direction from the front to the back of the paper surface is a downward direction of the vertical direction Z. In FIGS. 2 and 3, a direction indicated by an arrow indicating the vertical direction Z is the upward direction of the vertical direction Z. A direction opposite to the direction indicated by the arrow indicating the vertical direction Z is the downward direction of the vertical direction Z.

As shown in FIGS. 1 and 2, the inspection device 10 includes a plurality of first elastomers 100 and a frame 150. As shown in FIG. 3, the inspection device 10 further includes a plurality of first plungers 110, a plurality of second plungers 120, a first pin plate 130, and a second pin plate 140. Each first plunger 110 includes a first tip contactor 112, a first columnar part 114, and a first receiving part 116. Each second plunger 120 includes a second tip contactor 122, a second columnar part 124, and a second receiving part 126. At least a portion of the first elastomer 100 such as a periphery of a hole 102 described later in the first elastomer 100, a conductive film 104 described later, each first plunger 110, and each second plunger 120 function as a probe. Each first plunger 110 and each second plunger 120 are biased in the vertical direction Z by at least a portion of the first elastomer 100 such as the periphery of the hole 102. It should be noted that FIGS. 1 and 2 do not show the hole 102, the conductive film 104, the first plungers 110, the second plungers 120, the first pin plate 130 and the second pin plate 140 shown in FIG. 3.

First, the plurality of first elastomers 100 and the frame 150 will be described with reference to FIGS. 1 and 2.

The frame 150 is, for example, made of metal. The frame 150 defines a plurality of openings 152 disposed in a grid. Each of the plurality of first elastomers 100 is provided in each of the plurality of openings 152. As a result, each first elastomer 100 is supported by an inner edge of the opening 152. The first plunger 110 is located below the first elastomer in the vertical direction Z and can be biased downward in the vertical direction Z. In this case, for example, even if force is applied to the first plunger 110 in a depth direction of the opening 152, that is, in the vertical direction Z when the inspection device 10 performs an inspection, spreading of each first elastomer 100 in a planar direction, that is, in a direction perpendicular to the vertical direction Z can be suppressed as compared with a case in which each first elastomer 100 is not supported by the inner edge of the opening 152. However, the inspection device 10 may not include the frame 150.

Each first elastomer 100 has a sheet shape. In one example, the first elastomer 100 is made of a polymeric material having elasticity, for example, a resin such as silicone or polyimide, or a rubber such as styrene-butadiene rubber (SBR).

As shown in FIG. 2, the first elastomer 100 includes a portion embedded in the opening 152 of the frame 150 (a portion located in the opening 152), a portion exposed from an upper opened end of the opening 152 of the frame 150, and a portion exposed from a lower opening end of the opening 152 of the frame 150. A width of the portion of the first elastomer 100 exposed from the upper opening end of the opening 152 in a left-right direction in the drawing is wider than a width of the upper opening end of the opening 152 in the left-right direction in the drawing. Accordingly, the portion of the first elastomer 100 exposed from the upper opening end of the opening 152 can be suppressed from exiting downward the frame 150 through the opening 152. A width of the portion of the first elastomer 100 exposed from the lower opening end of the opening 152 in a left-right direction in the drawing is wider than a width of the lower opening end of the opening 152 in the left-right direction in the drawing. Accordingly, the portion of the first elastomer 100 exposed from the lower opening end of the opening 152 can be suppressed from exiting upward the frame 150 through the opening 152. It should be noted that the first elastomer 100 may not include the portion exposed from the upper opened end of the opening 152 of the frame 150 and the portion exposed from the lower opening end of the opening 152 of the frame 150. Alternatively, the first elastomer 100 may include only one of the portion exposed from the upper opened end of the opening 152 of the frame 150 and the portion exposed from the lower opening end of the opening 152 of the frame 150. The width of the portion of the first elastomer 100 exposed from the opening end of the opening 152 in the left-right direction in the drawing may be equal to or less than the width of the opening end of the opening 152 in the left-right direction in the drawing.

Next, the details of each first elastomer 100 will be described with reference to FIG. 3.

The first elastomer 100 defines a plurality of holes 102 that penetrate the first elastomer 100 along the vertical direction Z.

The conductive film 104 is formed on an inner wall of each hole 102. In one example, the conductive film 104 includes metal such as at least one selected from the group consisting of nickel, copper, and gold. The conductive film 104 is, for example, a multilayer film of these metals.

Each hole 102 is hollow. In this case, as compared with a case in which the conductive film 104 is formed on the inner wall of the hole 102 and the hole 102 is solid (the hole 102 is filled), a material and a process for making the hole 102 solid are unnecessary, and a manufacturing cost of the inspection device 10 can be reduced.

The first plunger 110 is located below the first elastomer 100. The first plunger 110 overlaps with the first elastomer 100 in the vertical direction Z. Specifically, the first plunger 110 overlaps with the hole 102 in the vertical direction Z. Accordingly, the first plunger 110 can be biased in a direction away from the second plunger 120, that is, downward by the first elastomer 100. The first plunger 110 is electrically connected to the conductive film 104. Accordingly, the first plunger 110 can be electrically connected to the second plunger 120 through the conductive film 104. If the first plunger 110 does not overlap with the hole 102 in the vertical direction Z, an electrical path such as a conductive material embedded in the first elastomer 100 needs to be provided separately from the conductive film 104 in order to electrically connect the first plunger 110 to the conductive film 104. When the first plunger 110 overlaps with the hole 102 in the vertical direction Z, however, the first plunger 110 can be directly connected to the conductive film 104 without through the electrical path such as the conductive material embedded in the first elastomer 100. Accordingly, as compared with a case in which the electrical path is provided, a material and a process for manufacturing the electrical path itself are unnecessary, and the manufacturing cost of the inspection device 10 can be reduced. It should be noted that the first plunger 110 may be offset from the hole 102 in a direction orthogonal to the vertical direction Z. Even in this case, the first plunger 110 can be connected to the conductive film 104 through the electrical path such as the conductive material embedded in the first elastomer 100.

The first tip contactor 112 includes metal such as at least one selected from the group consisting of rhodium, ruthenium, iridium, tungsten, and tantalum.

A width of the first tip contactor 112 is narrowed from a base end to a tip of the first tip contactor 112. The first tip contactor 112 is a conic solid such as a cone or a pyramid, and has a tapered shape from the base end to the tip of the first tip contactor 112. A tip of the first tip contactor 112 has a flat surface of, for example, equal to or more than 1 μm and equal to or less than 20 μm. However, the shape of the tip of the first tip contactor 112 is not limited to this example.

The first columnar part 114 includes metal such as at least one selected from the group consisting of copper and nickel.

The first columnar part 114 is connected to the base end of the first tip contactor 112. The first tip contactor 112 and the first columnar part 114 may be integrated or separate. A height of the first columnar part 114 is, for example, equal to or more than 5 μm and equal to or less than 300 μm. The first columnar part 114 is a column such as a cylinder or a prism. When the first columnar part 114 is a cylinder, a diameter of the first columnar part 114 is, for example, equal to or more than 20 μm and equal to or less than 500 μm. However, the shape of the first columnar part 114 is not limited to this example.

The first receiving part 116 includes metal such as at least one selected from the group consisting of copper and nickel.

The first receiving part 116 is connected to an end portion of the first columnar part 114 opposite to the first tip contactor 112. The first columnar part 114 and the first receiving part 116 may be integrated or separated. The first receiving part 116 has a width wider than a width of the first columnar part 114. A thickness of the first receiving part 116 is, for example, equal to or more than 5 μm and equal to or less than 200 μm. An upper surface of the first receiving part 116 is flat. However, at least one convex part may be formed on the upper surface of the first receiving part 116.

The first pin plate 130 is made of, for example, polyimide, liquid crystal polymer, or glass substrate.

The first pin plate 130 defines a plurality of first through-holes 132. Each of the plurality of first plungers 110 is inserted into each of the plurality of first through-holes 132. The plurality of first plungers 110 can be arranged at a minute pitch (narrow pitch) of, for example, equal to or more than 10 μm and equal to or less than 500 μm.

At least a portion of the first tip contactor 112 is exposed from a lower end of the first through-hole 132 of the first pin plate 130. At least a portion of the first columnar part 114 penetrates the first through-hole 132. The first receiving part 116 is located between an upper surface of the first pin plate 130 and a lower surface of the first elastomer 100. The width of the first receiving part 116 in the left-right direction in the drawing is wider than a width of the first through-hole 132 in the left-right direction in the drawing. Accordingly, the first receiving part 116 is caught by a peripheral portion of an opening end of the first through-hole 132 on the upper surface of the first pin plate 130. In this case, even if the first plunger 110 is biased downward by the first elastomer 100, the first receiving part 116 can be suppressed from exiting downward the first pin plate 130 through the first through-hole 132. Thus, as compared with a case in which the first receiving part 116 is not provided, even if a length of the first plunger 110 (a length of the first columnar part 114) is shortened, the first plunger 110 is unlikely to exit below the first pin plate 130. The length of the first plunger 110 can be shortened, and the first plunger 110 can be applied to an inspection in a high frequency band of equal to or more than 1 GHz and equal to or less than 100 GHz.

The second plunger 120 is located above the first elastomer 100. The second plunger 120 overlaps with the first elastomer 100 in the vertical direction Z. Specifically, the second plunger 120 overlaps with the hole 102 in the vertical direction Z. Accordingly, the second plunger 120 can be biased in a direction away from the first plunger 110, that is, upward by the first elastomer 100. The second plunger 120 is electrically connected to the conductive film 104. Accordingly, the second plunger 120 can be electrically connected to the first plunger 110 through the conductive film 104. If the second plunger 120 does not overlap with the hole 102 in the vertical direction Z, an electrical path such as a conductive material embedded in the first elastomer 100 needs to be provided separately from the conductive film 104 in order to electrically connect the second plunger 120 to the conductive film 104. When the second plunger 120 overlaps with the hole 102 in the vertical direction Z, however, the second plunger 120 can be directly connected to the conductive film 104 without through the electrical path such as the conductive material embedded in the first elastomer 100. Accordingly, as compared with a case in which the electrical path is provided, the material and the process for manufacturing the electrical path itself are unnecessary, and the manufacturing cost of the inspection device 10 can be reduced. It should be noted that the second plunger 120 may be offset from the hole 102 in a direction orthogonal to the vertical direction Z. Even in this case, the second plunger 120 can be connected to the conductive film 104 through the electrical path such as the conductive material embedded in the first elastomer 100.

The second pin plate 140 defines a plurality of second through-holes 142. Each of the plurality of second plungers 120 is inserted into each of the plurality of second through-holes 142 in the same manner as the plurality of first plungers 110 and the first pin plate 130.

According to the present embodiment, as compared with a case in which the plunger is biased by a spring, the first elastomer 100 plays a role of compression and extension of the spring, and the conductive film 104 plays a role of conduction of the spring. If the plunger is biased by the spring, a free length of the spring needs to be short to compare the free lengths of the probe. In this case, however, it is difficult to achieve a sufficient stroke. On the other hand, in the present embodiment, there is no need to use the spring. Accordingly, as compared with a case in which the plunger is biased by the spring, a natural length of the probe can be shortened while achieving the stroke having a sufficient length.

It should be noted that, in the present embodiment, the case has been described in which the first plunger 110 and the second plunger 120 overlap with the first elastomer 100 in the vertical direction Z. However, the first elastomer 100 and the second plunger 120 may overlap with the first elastomer 100 in a direction different from the vertical direction Z.

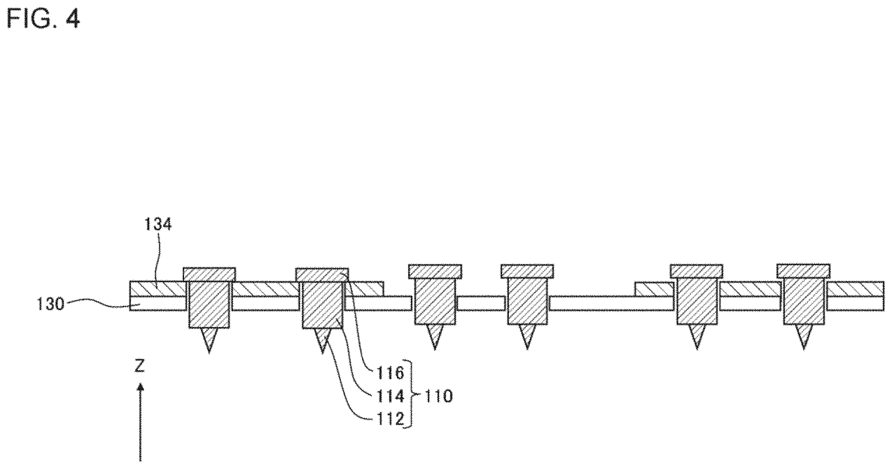

FIG. 4 is a cross-sectional view for describing the details of the first plunger 110 and the first pin plate 130.

A first conductive pattern 134 is provided on the upper surface of the first pin plate 130. The first conductive pattern 134 is, for example, a metal pattern.

At least some of the first plungers 110 of the plurality of first plungers 110 are electrically connected to each other through the first conductive pattern 134. The first conductive pattern 134 functions as a connection part. In the example shown in FIG. 4, two first plungers 110 on the left side in the drawing are electrically connected to each other through the first conductive pattern 134 on the left side in the drawing. Two first plungers 110 on the right side in the drawing are electrically connected to each other through the first conductive pattern 134 on the right side in the drawing. On the other hand, the first conductive pattern 134 is not provided in central two first plungers 110 in the drawing. As a result, the potential of the plurality of first plungers 110 electrically connected through the first conductive pattern 134 can be commonalized. In this case, the potential of the plurality of first plungers 110 can be commonalized with a simpler structure than in a case in which the potential is supplied to each plunger through separate electrical paths.

A ground potential or a power supply potential is applied to the first conductive pattern 134, for example. As one example, some of the first plungers 110 of the plurality of first plungers 110 are supplied with a common ground potential through the first conductive pattern 134. On the other hand, at least some of remaining first plungers 110 of the plurality of first plungers 110 are supplied with a common power supply potential through other first conductive patterns 134.

When the plurality of first plungers 110 are electrically connected to each other through the first conductive pattern 134 provided on the first pin plate 130, the first plungers 110 that is to have common potential can be optionally selected depending on the shape of the first conductive pattern 134. Accordingly, the first plunger 110 that is to have common potential is easily selected as compared with, for example, a case in which the plurality of first plungers 110 are electrically connected to each other through the conductive pattern provided on the lower surface of the first elastomer 100. However, the plurality of first plungers 110 may be electrically connected to each other through the conductive pattern provided on the first elastomer 100.

At least a portion of the first receiving part 116 overlaps with the first conductive pattern 134 on the opening end of the first through-hole 132 of the first pin plate 130. By inserting the first plunger 110 into the first through-hole 132 from a side of the first pin plate 130 on which the first conductive pattern 134 is located, the first receiving part 116 contacts with the first conductive pattern 134 and the first plunger 110 can be electrically connected to the first conductive pattern 134.

In the present embodiment, the conductive pattern may be provided only on the first pin plate 130 of the first pin plate 130 and the second pin plate 140. In this case, the cost of the inspection device 10 can be reduced as compared with a case in which the conductive pattern is provided on both the first pin plate 130 and the second pin plate 140. When an inspection target of the inspection device 10, such as an electronic device, is disposed on a side on which the first pin plate 130 is located, various types of conductive patterns needs to be prepared on the first pin plate 130 side. On the other hand, in the above case, on a side on which the second pin plate 140 is located, a substrate of the inspection device 10 is disposed, and there is no need to form various types of conductive patterns. However, the conductive patterns may be provided on both the first pin plate 130 and the second pin plate 140.

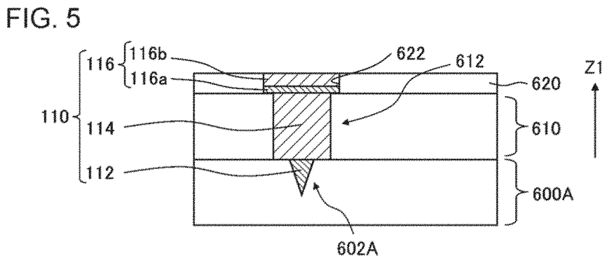

FIG. 5 is a cross-sectional view for describing a method of manufacturing the first plunger 110 according to the embodiment.

The method of manufacturing the first plunger 110 will be described with reference to FIG. 5. It should be noted that the second plunger 120 can also be manufactured in the same manner as described below. FIG. 5 shows a normal direction Z1 of a surface of the metal base 600A on which the recess part 602A is formed.

First, the recess part 602A is formed in the metal base 600A. Next, a portion of the first resist film 610 is formed on the metal base 600A. A first opening 612 is provided in the first resist film 610. Next, a first conductive material as the first tip contactor 112 is formed by plating and the first conductive material is embedded in the recess part 602A. As a result, the first tip contactor 112 is formed in the recess part 602A.

Next, a thickness of the first resist film 610 is further increased. Next, a second conductive material as the first columnar part 114 is formed by plating and the second conductive material is embedded in the first opening 612. As a result, the first columnar part 114 is formed in the first opening 612.

Next, a first seed layer 116a is formed on the first columnar part 114 and the first resist film 610.

Next, a second resist film 620 is formed on the first resist film 610. A second opening 622 is provided in the second resist film 620. Next, a third conductive material as the first plating layer 116b is formed by plating and the third conductive material is embedded in the second opening 622. As a result, the first receiving part 116 is formed in the second opening 622.

Next, the first resist film 610 and the second resist film 620 are removed by, for example, chemical solution treatment. Next, the first plunger 110 is removed from the metal base 600A.

According to the present embodiment, the first tip contactor 112 can be formed by using the recess part 602A of the metal base 600A as a die. The first columnar part 114 can be formed by using the first opening 612 of the first resist film 610 as a die. The first receiving part 116 can be formed by using the second opening 622 of the second resist film 620 as a die. Accordingly, the first plunger 110 can be miniaturized as compared with a case in which the first tip contactor 112 is formed by polishing.

In the above, the embodiments of the present invention have been described with reference to the drawings, but these are examples of the present invention, and various configurations other than the above can be adopted.

According to the present specification, the following aspects are provided.

### (Aspect 1)

Aspect 1 is an inspection device including a plurality of plungers, and a connection part electrically connecting at least some of the plungers of the plurality of plungers to each other.

According to Aspect 1, the potential of the plurality of plungers is commonalized by electrically connecting the plurality of plungers to each other. In this case, the potential of the plurality of plungers can be commonalized with a simpler structure than in a case in which the potential is supplied to each plunger through separate electrical paths.

### (Aspect 2)

Aspect 2 is the inspection device according to Aspect 1, further including a pin plate having a plurality of through-holes into which the plurality of plungers are inserted, and a conductive pattern provided in the pin plate and electrically connecting the at least some of the plungers to each other.

According to Aspect 2, the plunger to have common potential can be optionally selected depending on the shape of the conductive pattern. Accordingly, the plungers to have common potential are easily selected as compared with, for example, a case in which the plurality of plungers are electrically connected to each other through the conductive pattern provided on the elastomer.

### (Aspect 3)

Aspect 3 is the inspection device according to Aspect 2, in which each of the plurality of plungers includes a columnar part and a receiving part connected to the columnar part and having a width wider than a width of the columnar part, the columnar part penetrates the through-hole of the pin plate, and at least a portion of the receiving part overlaps with the conductive pattern over an opening end of the through-hole.

According to Aspect 3, by inserting the plunger into the through-hole from the side of the pin plate on which the conductive pattern is located, the receiving part contacts with the conductive pattern and the plunger can be electrically connected to the conductive pattern.

This application claims priority based on Japanese Patent Application No. 2020-106767 filed on Jun. 22, 2020, the entire disclosure of which is incorporated herein by reference.

### REFERENCE SIGNS LIST

10 inspection device

100 first elastomer

102 hole

104 conductive film

110 first plunger

112 first tip contactor

114 first columnar part

116 first receiving part

116a first seed layer

116b first plating layer

120 second plunger

122 second tip contactor

124 second columnar part

126 second receiving part

130 first pin plate

132 first through-hole

134 first conductive pattern

140 second pin plate

142 second through-hole

150 frame

152 opening

600A metal base

602A recess part

610 first resist film

612 first opening

620 second resist film

622 second opening

Z vertical direction

Z1 normal direction

1. An inspection device comprising:
a plurality of plungers; and
a connection part electrically connecting at least some of the plungers of the plurality of plungers to each other.

2. The inspection device according to claim 1, further comprising:
a pin plate having a plurality of through-holes into which the plurality of plungers are inserted; and
a conductive pattern provided in the pin plate and electrically connecting the at least some of the plungers to each other.

3. The inspection device according to claim 2,
wherein each of the plurality of plungers includes a columnar part and a receiving part connected to the columnar part and having a width wider than a width of the columnar part,
the columnar part penetrates the through-hole of the pin plate, and
at least a portion of the receiving part overlaps with the conductive pattern over an opening end of the through-hole.
